(19) United States
(12) Patent Application Publication
(10) Pub. No.: US 2012/0037222 A1
(43) Pub. Date: Feb. 16, 2012

(54) Smart Photovoltaic Assembly and Photovoltaic System

(75) Inventors: Palvin Chee Leong Chan, Seattle, WA (US); Lang Guo, Wuxi (CN); Rui Huang, Wuxi (CN)

(73) Assignee: WUXI SUNTECH POWER CO., LTD., Wuxi (CN)

(21) Appl. No.: 13/209,637

(22) Filed: Aug. 15, 2011

(30) Foreign Application Priority Data
Aug. 13, 2010 (CN) 201010255504.X

(51) Int. Cl. H01L 31/02

(52) U.S. Cl. 136/256

(57) ABSTRACT

A smart photovoltaic assembly and a photovoltaic system are provided. The smart photovoltaic assembly comprises a photovoltaic assembly main body, an installation plate disposed on a back surface of the photovoltaic assembly main body, and a current leading terminal connector provided on the installation plate for leading an electric current line from the photovoltaic assembly main body, wherein the current leading terminal connector has a first connector interface adapted for connecting with a second connector interface of a complementary electronic device. The current leading terminal connector is in electrical connection with the complementary electronic device by mutual connection of the first connector interface and the second connector interface. The photovoltaic system comprises the above mentioned smart photovoltaic assembly, wherein the electronic device may be a diode module, an electric voltage converting device, a monitor or other types of electronic devices according to the need of a user.

### CROSS-REFERENCE TO RELATED APPLICATIONS

This application claims priority to foreign Patent Application CN 201010255504.X, filed on Aug. 13, 2010, the disclosure of which is incorporated herein by reference in its entirety.

### FIELD OF THE INVENTION

This invention relates to the photovoltaic (PV) field of solar energy, particularly to a smart photovoltaic assembly and a photovoltaic system that has a simple structure and is easy to install.

### BACKGROUND OF THE INVENTION

Solar energy, as a new energy, has the advantage of infinite exploitation compared with traditional fossil fuels. As the international energy situation becomes severe, every country is making even greater efforts to develop the solar energy industry. As a result, the application of solar energy is becoming wider, such as satellite solar plates in the field of aviation and aerospace and solar water heaters in daily life, etc.

The current prevailing manner of using solar energy is converting solar energy into electric energy via the photovoltaic effect of semiconductor materials. A solar cell is a typical photo-electric conversion device. In practical application, usually a photovoltaic system is formed with a solar module as the core. A complete photovoltaic power generation system mainly includes a solar assembly, a terminal box, voltage transformers, such as an inverter, and various instruments. The basic principle is: a solar assembly gets solar energy and converts it into electric energy; a terminal box leads the electric energy; the leaded direct current electricity is converted into the needed alternate current electricity via voltage transformers; finally, the alternate current electricity is directly incorporated to a public power grid for use; or the electric energy is stored in a storage battery and is controlled by a charge/discharge controller, wherein the storage battery receives the electric energy from the solar assembly when charging and provides electricity when discharging.

A current standard photovoltaic assembly comprises a solar module and a terminal box fixed at the back of the solar module, the terminal box having a by-pass diode therein for protecting the solar module. Other electronic devices needed for the photovoltaic system, such an inverter and other instruments, are provided and installed separately from the solar module and need additional installation structures and spaces as well as connecting materials. As shown in FIG. 1, in a schematic drawing of a connecting structure between a terminal box and an inverter of a photovoltaic system of the prior arts, the terminal box 14 is directly adhered to the back of the solar module 11 and the inverter 12 is fixed independently and is connected with the solar module 11 through an electrical wire 13.

Thus, more labor and materials are needed when producing and installing the photovoltaic assembly and system of the prior arts, which is an obstacle for controlling the costs of production, installation and maintenance of the assembly and system. In addition, since the terminal box and the assembly are installed together, the function of the assembly is relatively limited.

### SUMMARY OF THE INVENTION

Embodiments of the present invention advantageously provide a smart photovoltaic assembly and a photovoltaic system that have a simple structure and are easy to install.

In one embodiment, a smart photovoltaic (PV) assembly comprises a photovoltaic assembly main body, an installation plate disposed on a back surface of the photovoltaic assembly main body, and a current leading terminal connector provided on the installation plate for leading an electric current line from the photovoltaic assembly main body, wherein the current leading terminal connector has a first connector interface adapted for connecting with a second connector interface of a complementary electronic device.

In one embodiment, both sides of the first connector interface are provided with a first locking socket or a first locking sheet, respectively.

In one embodiment, the first connector interface at least comprises one anode connector terminal and one cathode connector terminal.

In one embodiment, the first connector interface further comprises intermediate connector terminals.

In one embodiment, wherein the number of the intermediate connector terminals of the first connector interface is two.

In one embodiment, the installation plate comprises a top plate and a side support portion which is formed by the edge portions of the top plate bending downwards and supports the top plate, and wherein the current leading terminal connector is provided at an end of a surface of the top plate.

In one embodiment, the top plate is provided with a plurality of installation holes which may be through holes, swallow-tailed grooves or other installation modes except through holes.

In one embodiment, the installation holes in the top plate are through holes and are arranged in a matrix, and wherein a width of an end of each through hole which is close to the current leading terminal connector is smaller than a width of an end of the through hole which is away from the current leading terminal connector.

In one embodiment, the through holes in the top plate are inverted “T” shaped or “L” shaped.

In one embodiment, the through holes at a middle portion of the top plate are inverted “T” shaped, and the through holes at both sides of the top plate are symmetrically arranged and “L” shaped.

In one embodiment, a side of the top plate of the installation plate which is close to the back surface of the photovoltaic assembly main body has a plurality of protruding ribs.

In one embodiment, the installation plate is adhered fixedly to the photovoltaic assembly main body via the side support portion and the ribs.

In one embodiment, the side support portion is provided with a plurality of heat emission holes.

In one embodiment, the installation plate is made of a plastic material.

In another embodiment, a photovoltaic system comprises the above smart photovoltaic assembly and a complementary electronic device detachably secured to the installation plate, the complementary electronic device having a second connector interface for matching with the first connector interface of the smart photovoltaic assembly, wherein the current leading terminal connector is in electrical connection with the complementary electronic device by mutual connection of the first connector interface and the second connector interface.

In one embodiment, both sides of the second connector interface are respectively provided with a second locking socket to be matched with the first locking sheet or a second locking sheet to be matched with the first locking socket, and wherein when the first connector interface and the second connector interface are plugged into each other, the first locking sheet is clipped with the second locking socket or the first locking socket is clipped with the second locking sheet.

In one embodiment, the second connector interface at least comprises one anode connector terminal and one cathode connector terminal.

In one embodiment, the second connector interface further comprises intermediate connector terminals.

In one embodiment, the number of the intermediate connector terminals of the second connector interface is two.

In one embodiment, the complementary electronic device comprises a diode module, a DC-AC conversion circuit, a DC-DC conversion circuit and/or an assembly monitoring circuit.

In one embodiment, a bottom surface of the complementary electronic device is provided with bottom hooks that are arranged in a matrix and are used to position the complementary electronic device to the top plate of the installation plate, wherein the bottom hooks are inserted into the installation holes and guide the complementary electronic device to move towards the current leading terminal connector, thereby realizing electrical connection.

In one embodiment, the cross-section of each bottom hook is inverted “T” shaped or “L” shaped.

The advantageous effects of this invention are many, including, for example, the electrical connection between the current leading terminal connector provided on the installation plate and the complementary electronic device is realized by directly plugging the connector interfaces, so that the structure of the photovoltaic system is simple, easy to install and can meet various demands of the users; the flexible selection of the needed electronic device also facilitates to have different functions, thereby saving the material cost and the manual installation cost of the system.

### BRIEF DESCRIPTION OF THE DRAWINGS

FIG. 1 is a schematic drawing of the connecting structure between a terminal box and an inverter of a known photovoltaic system;

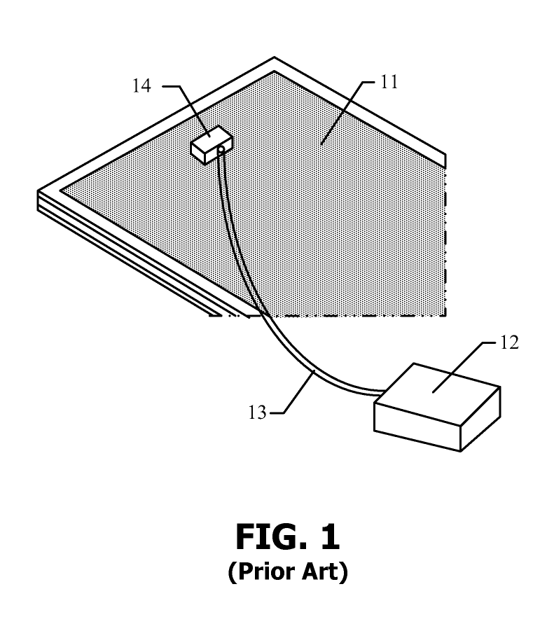

FIG. 2 is a schematic drawing of the structure of photovoltaic system according to an embodiment of the present invention;

FIG. 3 is a schematic drawing of the structure of the installation plate in FIG. 2;

FIG. 4 is the front view of FIG. 3;

FIG. 5 is the side view of FIG. 3;

FIG. 6 is a schematic drawing of the structure of the electronic device in FIG. 2;

FIG. 7 is the front view of FIG. 6;

FIG. 8 is a schematic drawing of the plugged structure of the installation plate and the electronic device in FIG. 2; and

FIG. 9 is a schematic drawing of the circuit of the photovoltaic system in FIG. 2.

### DETAILED DESCRIPTION

The invention will now be described with reference to the drawing figures, in which like reference numerals refer to like parts throughout.

### System

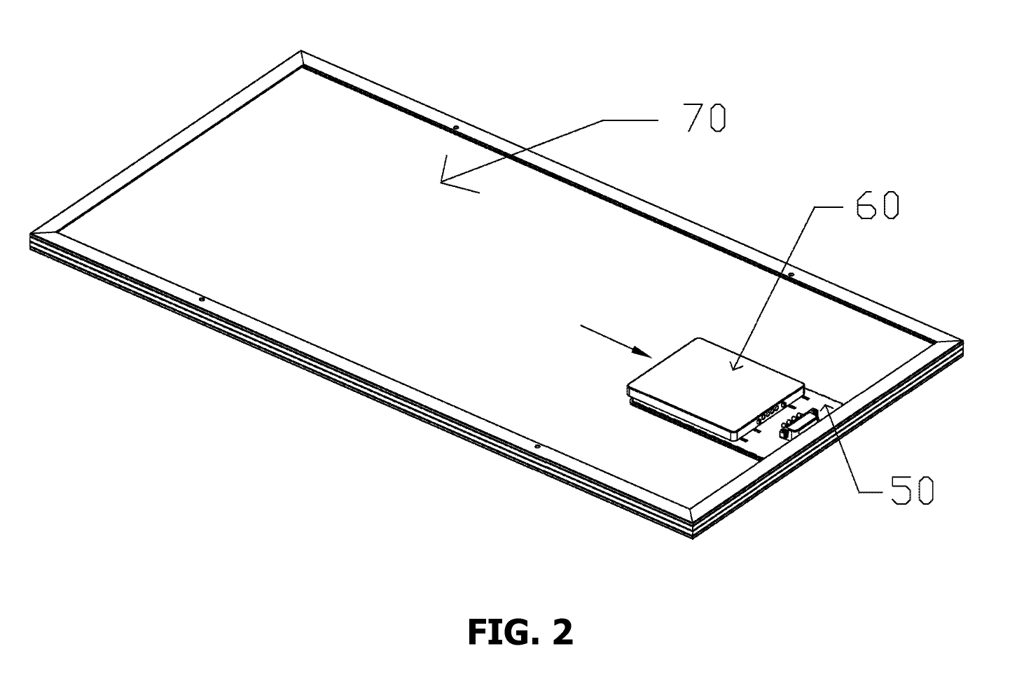

As shown in FIGS. 2, 3, 6 and 8, the photovoltaic system of one embodiment of this invention comprises a smart photovoltaic assembly and an complementary electronic device 60; the smart photovoltaic assembly further comprises a photovoltaic assembly main body 70, an installation plate 50 and a current leading terminal connector 54 which is fixed on the installation plate 50 and which is used for leading an electric current, wherein the installation plate 50 is fixed on a back surface of the photovoltaic assembly main body 70, and the current leading terminal connector 54 has a first connector interface 541; the electronic device 60 is fixed on the installation plate 50 and has a second connector interface 611 to be matched with the first connector interface 541, wherein the current leading terminal connector 54 is in electrical connection with the electronic device 60 by mutual plugging of the first connector interface 541 and the second connector interface 611.

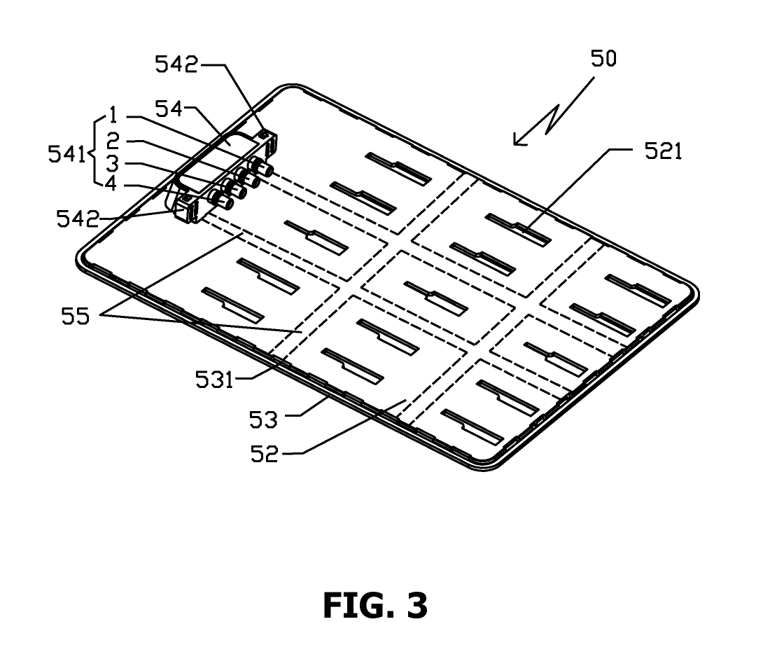

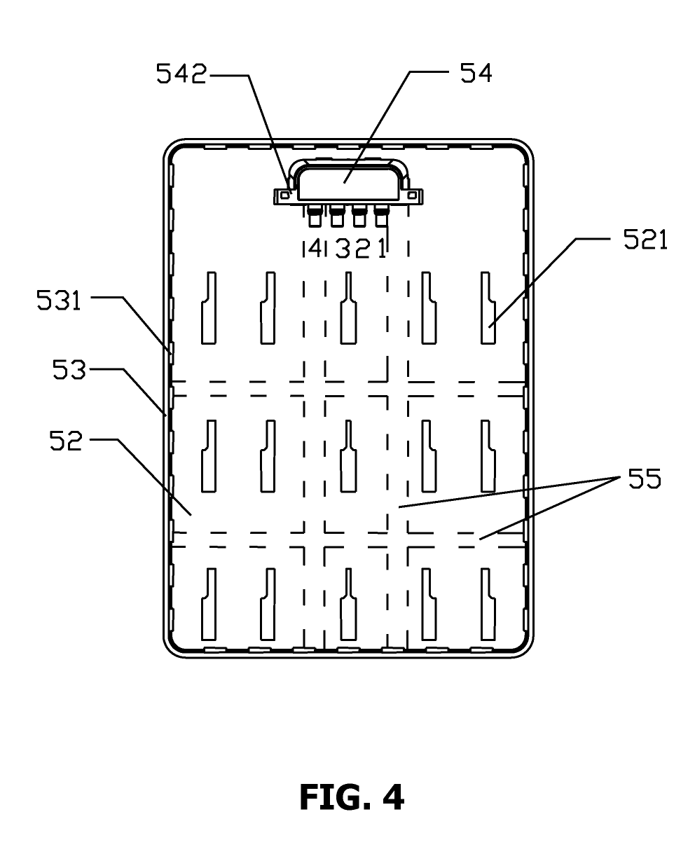

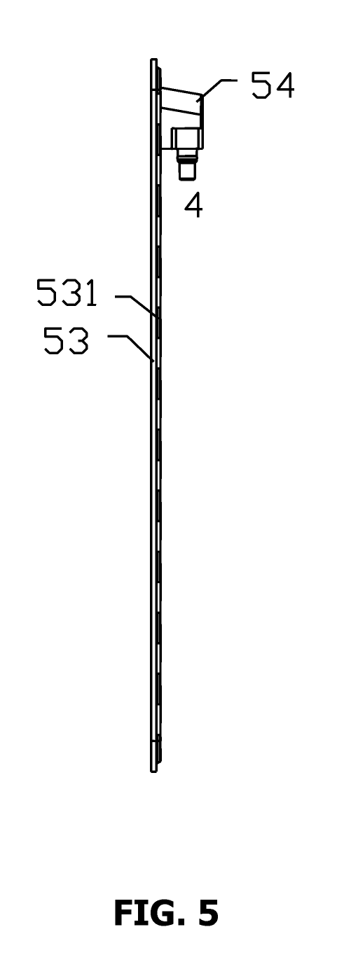

As shown in FIGS. 3-5, the installation plate 50 comprises a top plate 52 and a side support portion 53 which is formed by the edge portions of the top plate 52 bending downwards and supports the top plate 52. A heat emission space is formed between the top plate 52 and the back surface of the photovoltaic assembly main body 70 via the side support portion 53. The current leading terminal connector 54 is provided at an end of a surface of the top plate 52. A side of the top plate 52 of the installation plate 50 which is close to the back surface of the photovoltaic assembly main body 70 has a plurality of protruding ribs 55 in both transverse and longitudinal directions. The installation plate 50 is adhered fixedly to the photovoltaic assembly main body 70 via the side support portion 53 and the ribs 55. Of course, the installation plate 50 may also be fixed in other manners.

With reference to FIG. 3, the first connector interface 541 comprises one anode connector terminal 1, a cathode connector terminal 4, a first intermediate connector terminal 2 and a second intermediate connector terminal 3, wherein the anode connector terminal 1 and the cathode connector terminal 4 are necessary, while the intermediate connector terminals are selective. The number of these connector terminals is determined according to the design of the smart photovoltaic assembly main body 70 of the photovoltaic system. If the photovoltaic assembly main body 70 has only two electric current leading terminals, i.e. one anode connector terminal and one cathode connector terminal, the intermediate connector terminals are kept unconnected.

The top plate 52 is provided with a plurality of through holes 521 which are arranged in a matrix, wherein a width of an end of each through hole 521 which is close to the current leading terminal connector 54 is smaller than a width of an end of the through hole which is away from the current leading terminal connector 54. The through holes 521 are inverted “T” shaped or “L” shaped, wherein the through holes 521 at a middle portion are inverted “T” shaped, and the through holes 521 at both sides are symmetrically arranged and “L” shaped, so that the electronic device 60 can be installed on the top plate 52. In fact, the through holes 521 can be arranged randomly and have any shape. The side support portion 53 is provided with a plurality of heat emission holes 531 along the length direction of the side support portion 53. The heat emission holes 531 may have any shape. To facilitate manufacturing, the heat emission holes 531 may be rectangular shaped or circular shaped, and the spacing between each two adjacent heat emission holes 531 is the same. Of course, the through holes 521 may be swallow-tailed grooves or may be replaced by installation holes of other modes than through holes.

The installation plate 50 corresponds to a pierced cover having through holes and may be formed integrally by a plastic material. The through holes 521 and the heat emission holes 531 may be formed in the formation of the installation plate 50 or may be formed separately after forming the installation plate 50. When the installation plate 50 is installed at a back surface of the photovoltaic assembly main body 70, a gap is formed between the top plate 52 and the photovoltaic assembly main body 70, and a heat emission passage is formed by the through holes 521 and the heat emission holes 531. When the installation plate 50 is made of a plastic material, the issue of grounding disappears.

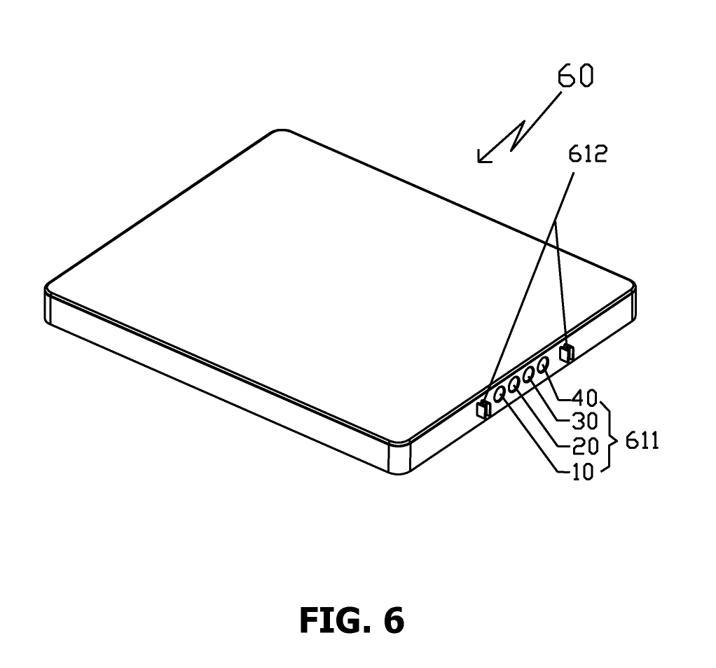

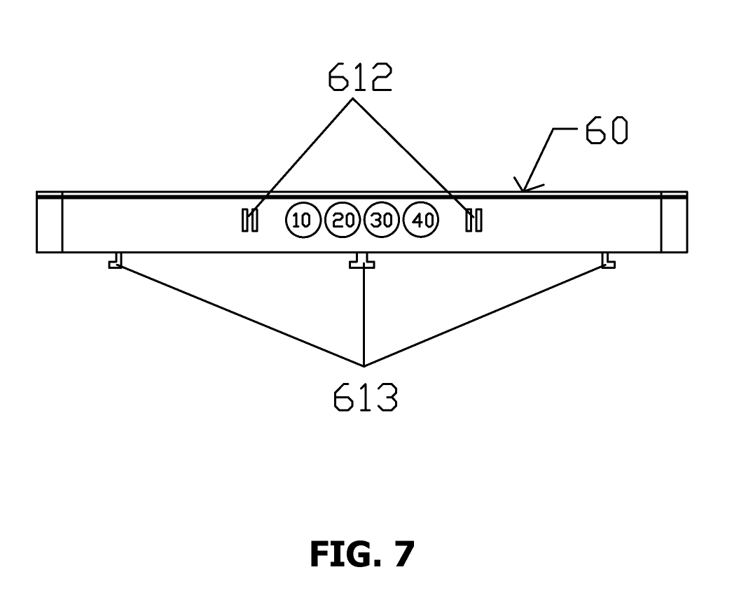

As shown in FIGS. 6-8, a bottom surface of the electronic device 60 is provided with bottom hooks 613 that are arranged in a matrix and are used to position the electronic device 60 to the top plate 52 of the installation plate 50, wherein the column spacing of the bottom hooks 613 matches that of the through holes 521 in the top plate 52, and the cross-section of the bottom hooks is inverted “T” shaped or “L” shaped. The bottom hooks 613 can pass through the through holes 521 and guide the electronic device 60 to move towards the current leading terminal connector 54, so that the first connector interface 541 and the second connector interface 611 plugged with each other, thereby realizing electrical connection. The bottom hooks 613 perform the functions of pre-positioning and guiding, thereby simplifying the installation process. Usually, there are more than three columns of bottom hooks 613, and the specific number of the columns may be determined according to the type and size of the electronic device 60. The through holes 521 may be swallow-tailed grooves or may be replaced by installation holes of other modes than through holes, so long as the installation holes can perform the function of guiding and positioning the bottom hooks 613, i.e. the bottom hooks 613 are inserted into the installation holes and guide the electronic device 60 to move towards the current leading terminal connector 54 so as to realize electrical connection.

The electronic device 60 may comprise a diode module, a DC-AC conversion circuit, a DC-DC conversion circuit and/or an assembly monitoring circuit, etc. The specific components of the electronic device 60 may be selected flexibly depending on the system requirements. For example, when the electronic device 60 is a diode module, the function of a common photovoltaic assembly can be realized; when the electronic device 60 is a conversion circuit, the function of an inverter can be realized.

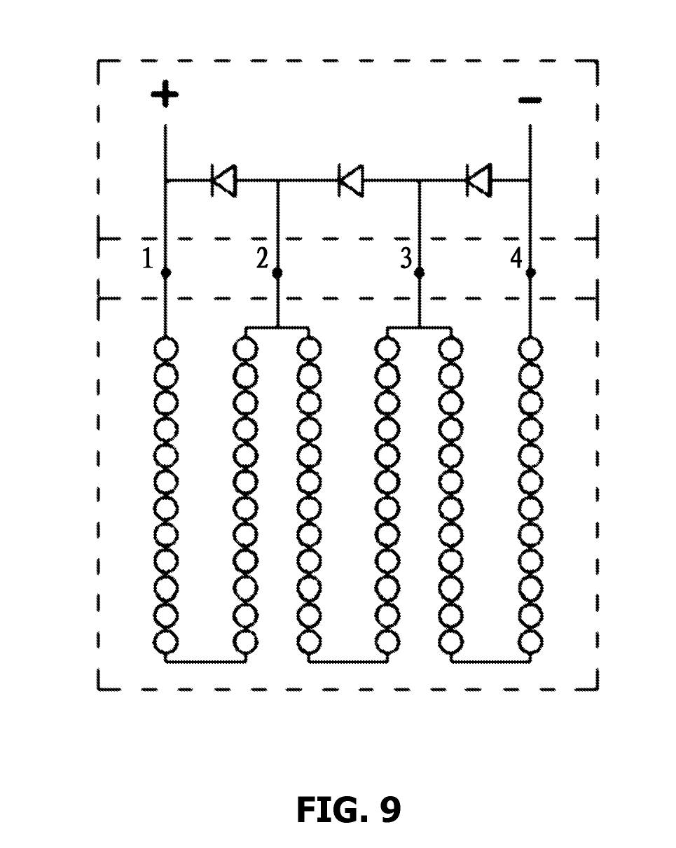

As shown in FIG. 6, corresponding to the first connector interface 541, the second connector interface 611 comprises one anode connector terminal 10, a first intermediate connector terminal 20, a second intermediate connector terminal 30, and a cathode connector terminal 40, wherein the anode connector terminal 10 and the cathode connector terminal 40 are necessary, while the first intermediate connector terminal 20 and the second intermediate connector terminal 30 are selective. The number of these connector terminals is determined according to the specific requirement of the circuit. With reference to FIG. 9, take a common diode module circuit for example, three by-pass diodes are sequentially connected between an anode and a cathode of the electronic device 60 in series; the anode connector terminal 10 is electrically connected to the anode of the electronic device 60; the cathode connector terminal 40, to the cathode of the electronic device 60; and the first intermediate connector terminal 20 and the second intermediate connector terminal 30, to an anode and a cathode of an intermediate diode, respectively.

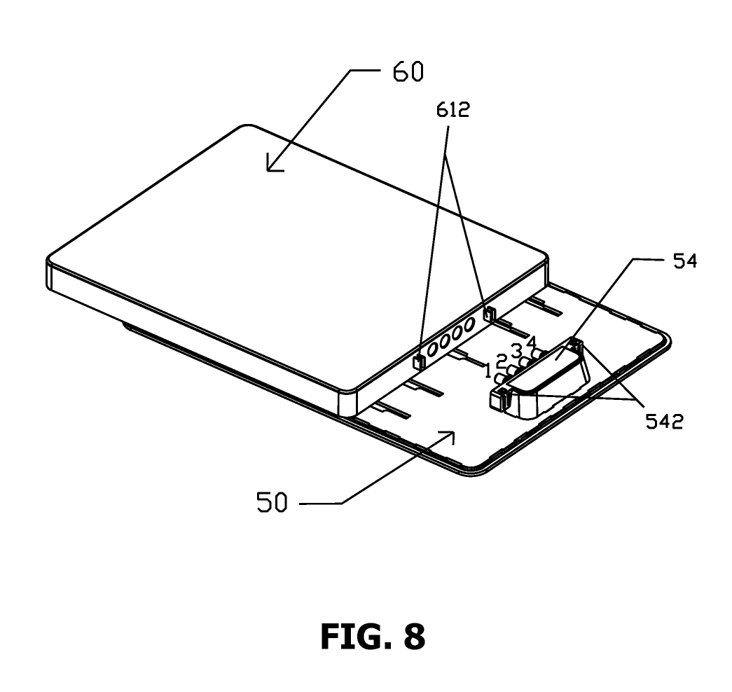

As shown in FIGS. 8-9, after the first connector interface 541 is plugged into the second connector interface 611, the anode connector terminal 1, the cathode connector terminal 4, the first intermediate connector terminal 2 and the second intermediate connector terminal 3 of the first connector interface 541 are electrically connected to the anode connector terminal 10, the cathode connector terminal 40, the first intermediate connector terminal 20 and the second intermediate connector terminal 30 of the second connector interface 611, respectively.

With reference to FIGS. 3, 6 and 8, both sides of the first connector interface 541 of the current leading terminal connector 54 are provided with a first locking socket 542, respectively; both sides of the second connector interface 611, with a second locking sheet 612, respectively. The first locking socket 542 is used for clipping with the corresponding second locking sheet 612 of the electronic device 60. The first locking socket 542 and the second locking sheet 612 form a locking mechanism so that the current leading terminal connector 54 and the electronic device 60 are fixedly clipped with each other. Of course, a first locking sheet may be provided to both sides of the first connector interface 541, respectively, and two corresponding second locking sockets are provided to the electronic device 60. The electronic device 60 with different sizes can be accommodated by increasing or reducing the distance between the first locking socket 542 and the first connector interface 541.

### Installation

The installation plate 50 is fixed to the photovoltaic assembly main body 70 via, for example, adhering, etc. The current leading terminal of the photovoltaic assembly main body 70 is electrically connected to the first connector interface 541 of the current leading terminal connector 54 on the installation plate 50 via, for example, soldering, etc.

The electronic device 60 is placed over the top plate 52 of the installation plate 50. Each of the bottom hooks 613 is aligned with and passes through the corresponding through hole 521 in the top plate 52 so as to pre-position the electronic device 60 on the top plate 52 of the installation plate 50. The electronic device 60 is pushed towards the current leading terminal connector 54. The bottom hooks 613 guide the electronic device 60 to move toward the current leading terminal connector 54 so that the first connector interface 541 and the second connector interface 611 are plugged with each other and the first locking socket 542 and the second locking sheet 612 are clipped with each other.

In a photovoltaic system embodiment, the electrical connection between the current leading terminal connector 54 provided on the installation plate 50 and the electronic device 60 is realized by directly plugging the connector interfaces, so that the structure of the photovoltaic system is simple, easy to install and can meet various demands of the users; the flexible selection of the needed electronic device also facilitates to have different functions, thereby saving the material cost and the manual installation cost of the system.

The many features and advantages of the invention are apparent from the detailed specification, and, thus, it is intended by the appended claims to cover all such features and advantages of the invention which fall within the true spirit and scope of the invention. Further, since numerous modifications and variations will readily occur to those skilled in the art, it is not desired to limit the invention to the exact construction and operation illustrated and described, and, accordingly, all suitable modifications and equivalents may be resorted to that fall within the scope of the invention.

What is claimed is:

1. A smart photovoltaic (PV) assembly, comprising:
a photovoltaic assembly main body,
an installation plate disposed on a back surface of the photovoltaic assembly main body, and
a current leading terminal connector provided on the installation plate for leading an electric current line from the photovoltaic assembly main body,
wherein the current leading terminal connector has a first connector interface adapted for connecting with a second connector interface of a complementary electronic device.

2. The smart photovoltaic assembly according to claim 1, wherein both sides of the first connector interface are provided with a first locking socket or a first locking sheet, respectively.

3. The smart photovoltaic assembly according to claim 1, wherein the first connector interface at least comprises one anode connector terminal and one cathode connector terminal.

4. The smart photovoltaic assembly according to claim 3, wherein the first connector interface further comprises intermediate connector terminals.

5. The smart photovoltaic assembly according to claim 4, wherein the number of the intermediate connector terminals of the first connector interface is two.

6. The smart photovoltaic assembly according to claim 1, wherein the installation plate comprises a top plate and a side support portion which is formed by the edge portions of the top plate bending downwards and supports the top plate, and wherein the current leading terminal connector is provided at an end of a surface of the top plate.

7. The smart photovoltaic assembly according to claim 6, wherein the top plate is provided with a plurality of installation holes.

8. The smart photovoltaic assembly according to claim 7, wherein the installation holes in the top plate are through holes and are arranged in a matrix, and wherein a width of an end of each through hole which is close to the current leading terminal connector is smaller than a width of an end of the through hole which is away from the current leading terminal connector.

9. The smart photovoltaic assembly according to claim 8, wherein the through holes in the top plate are inverted T-shaped or L-shaped.

10. The smart photovoltaic assembly according to claim 9, wherein the through holes at a middle portion of the top plate are inverted T-shaped, and the through holes at both sides of the top plate are symmetrically arranged and L-shaped.

11. The smart photovoltaic assembly according to claim 6, wherein a side of the top plate of the installation plate which is close to the back surface of the photovoltaic assembly main body has a plurality of protruding ribs.

12. The smart photovoltaic assembly according to claim 6, wherein the side support portion is provided with a plurality of heat emission holes.

13. The smart photovoltaic assembly according to claim 6, wherein the installation plate is adhered fixedly to the photovoltaic assembly main body via the side support portion and the ribs.

14. The smart photovoltaic assembly according to claim 1, wherein the installation plate is made of a plastic material.

15. A photovoltaic (PV) system comprising a smart photovoltaic assembly according to claim 1 and a complementary electronic device detachably secured to the installation plate, the complementary electronic device having a second connector interface for matching with the first connector interface of the smart photovoltaic assembly, wherein the current leading terminal connector is in electrical connection with the complementary electronic device by mutual connection of the first connector interface and the second connector interface.

16. The photovoltaic system according to claim 15, wherein both sides of the second connector interface are respectively provided with a second locking socket to be matched with the first locking sheet or a second locking sheet to be matched with the first locking socket, and wherein when the first connector interface and the second connector interface are plugged into each other, the first locking sheet is clipped with the second locking socket or the first locking socket is clipped with the second locking sheet.

17. The photovoltaic system according to claim 15, wherein a bottom surface of the complementary electronic device is provided with bottom hooks that are arranged in a matrix and are used to position the complementary electronic device to the top plate of the installation plate, wherein the bottom hooks are inserted into the installation holes and guide the complementary electronic device to move towards the current leading terminal connector, thereby realizing electrical connection.

18. The photovoltaic system according to claim 15, wherein the second connector interface comprises at least one anode connector terminal and one cathode connector terminal.

19. The photovoltaic assembly according to claim 18, wherein the second connector interface further comprises intermediate connector terminals.

20. The photovoltaic assembly according to claim 19, wherein the number of the intermediate connector terminals of the second connector interface is two.

21. The photovoltaic system according to claim 15, wherein the complementary electronic device comprises a diode module, a DC-AC conversion circuit, a DC-DC conversion circuit and/or an assembly monitoring circuit.

22. The photovoltaic system according to claim 15, wherein the cross-section of each bottom hook is inverted T-shaped or L-shaped.
